(19) United States
(12) Patent Application Publication
(10) Pub. No.: US 2024/0324281 A1
(43) Pub. Date: Sep. 26, 2024

(54) APPARATUS FOR MANUFACTURING DISPLAY APPARATUS AND METHOD OF MANUFACTURING DISPLAY APPARATUS

(71) Applicant: Samsung Display Co., Ltd., Yongin-si (KR)

(72) Inventors: Seil Kim, Yongin-si (KR); Minchul Song, Yongin-si (KR); Sangshin Lee, Yongin-si (KR); Seungjin Lee, Yongin-si (KR); Sangheon Jeon, Yongin-si (KR)

(21) Appl. No.: 18/421,655

(22) Filed: Jan. 24, 2024

(30) Foreign Application Priority Data
Mar. 22, 2023 (KR) 10-2023-0037534

(51) Int. Cl. H10K 59/12; C25D 5/02

(52) U.S. Cl. CPC H10K 59/1201; C25D 5/022

(57) ABSTRACT

An apparatus for manufacturing a display apparatus includes: a mask assembly facing a display substrate; and a deposition source facing the mask assembly on a side opposite the display substrate. The mask assembly includes: a mask frame having an opening area; a first mask on the mask frame and having a first opening; and a second mask on the first mask and having a plurality of second openings overlapping with the first opening and positioned within a circumference of the first opening in a plan view. A corner curvature radius of each of the second openings is 6 μm or less.

### CROSS-REFERENCE TO RELATED APPLICATION

This application claims priority to and the benefit of Korean Patent Application No. 10-2023-0037534, filed on Mar. 22, 2023, in the Korean Intellectual Property Office, the entire disclosure of which is incorporated herein by reference.

### BACKGROUND

### 1. Field

Aspects of embodiments of the present disclosure relate to an apparatus for manufacturing a display apparatus and a method of manufacturing the display apparatus.

### 2. Description of the Related Art

Recently, the use (or application) of display apparatuses has diversified. In addition, as display apparatuses have become thinner and lighter, their range of use has gradually been extended.

As the area occupied by a display area in display apparatuses expands, various functions that are combined or associated with display apparatuses have been added. Rather than extending a display area to add various functions, research has been conducted into a display apparatus having a region for adding various functions, as well as displaying images, inside the display area.

Among the types of display apparatuses, an organic light-emitting display apparatus may include a pixel electrode and an opposite electrode. The opposite electrode may be formed by using various suitable methods, one of which is to pass a deposition material through a mask to be deposited on a surface of a substrate. In this case, to improve light transmittance, the opposite electrode may not be arranged in (e.g., may not be deposited in) a partial region of the substrate.

The above Background description is technical information possessed by the inventor to derive the present disclosure or was obtained during the process of deriving the present disclosure. Therefore, the above information is not necessarily known art open to the general public prior to the filing of the present disclosure.

### SUMMARY

Embodiments of the present disclosure include an apparatus for manufacturing a display apparatus and a method of manufacturing the display apparatus in which deposition quality and transmittance (e.g., light transmittance) of the display apparatus is improved.

However, this aspect and feature of the present disclosure is merely an example, and the present disclosure is not limited thereto.

Additional aspects and features will be set forth, in part, in the description that follows and, in part, will be apparent from the description or may be learned by practice of the embodiments of the present disclosure described herein.

According to an embodiment of the present disclosure, an apparatus for manufacturing a display apparatus includes: a mask assembly facing a display substrate and a deposition source facing the mask assembly on a side opposite the display substrate. The mask assembly includes: a mask frame having an opening area; a first mask on the mask frame and having a first opening; and a second mask on the first mask and having a plurality of second openings overlapping with the first opening and positioned within a circumference of the first opening in a plan view. A corner curvature radius of each of the second openings being 6 μm or less.

A shortest distance between two adjacent ones of the second openings may be 10 μm or less.

A minimum width of a rib of the second mask defining the second openings may be 10 μm or less.

A manufacturing tolerance at a point of a circumference of each of the second openings may be ±1.5 μm or less.

An average manufacturing tolerance of each of the second openings may be ±1.5 μm or less.

The second mask may include a hump protruding from an inner surface of the second openings, and a height from one surface of the second mask facing the display substrate to the hump may be 0.5 μm or less.

A width of the hump protruding from the inner surface of the second opening in the plan view may be 1 μm or less.

The display substrate may have a first display area and a second display area at least partially surrounded by the first display area in the plan view, and the first opening may be at a position corresponding to the second display area in the plan view.

The second display area may have a transmissive area at where a display element is not arranged, and the second openings may be at a position corresponding to the transmissive area in the plan view.

According to another embodiment of the present disclosure, a method of manufacturing a display apparatus includes: arranging a display substrate inside a chamber; manufacturing a mask assembly; arranging the mask assembly to face the display substrate; and sublimating a deposition material to pass through the mask assembly to be deposited on the display substrate. The mask assembly includes a first mask having a first opening and a second mask having a second opening, and the second mask is manufactured by electro-forming.

The manufacturing of the second mask using electro-forming may include: arranging a photoresist on a mask substrate; arranging an exposure mask having an exposure opening on the photoresist; removing the photoresist in a region corresponding to the exposure opening by developing the photoresist; plating a metal on the region from which the photoresist is removed; and removing the remaining photoresist and the mask substrate.

A curvature radius of a corner of the second opening may be 6 μm or less.

The second mask may have a plurality of the second openings, and the second openings may overlap with the first opening and are positioned within a circumference of the first opening in a plan view.

A shortest distance between two adjacent ones of the second openings may be 10 μm or less.

A minimum width of a rib of the second mask defining the second openings may be 10 μm or less.

The second mask may include a hump protruding from an inner surface of the second opening, and a height from one surface of the second mask facing the display substrate to the hump may be 0.5 μm or less.

A width of the hump protruding from the inner surface of the second opening in a plan view may be 1 μm or less.

The display substrate may have a first display area and a second display area at least partially surrounded by the first display area in a plan view, and the arranging of the mask assembly may include aligning the first opening at a position corresponding to the second display area in the plan view.

The second display area may have a transmissive area at where a display element is not arranged, and the arranging of the mask assembly may include aligning the second opening at a position corresponding to the transmissive area in the plan view.

An average manufacturing tolerance of the second opening may be ±1.5 μm or less.

These and/or other aspects and features of the present disclosure will become apparent and more readily appreciated from the following description of embodiments thereof, the accompanying drawings, and claims.

### BRIEF DESCRIPTION OF THE DRAWINGS

The above and other aspects and features of the present disclosure will be more apparent from the following description taken in conjunction with the accompanying drawings, in which:

FIG. 1 is a schematic perspective view of a display apparatus according to an embodiment;

FIG. 2 is a schematic cross-sectional view of the display apparatus taken along the line I-I′ of FIG. 1 according to an embodiment;

FIG. 3 is a schematic plan view of configurations of sub-pixels and a transmissive portion arranged in a first display area and a second display area of a display apparatus according to an embodiment;

FIG. 4 is a schematic cross-sectional view of the display apparatus taken along the lines II-II′ and III-III′ of FIG. 3 according to an embodiment;

FIG. 5 is a cross-sectional view of an apparatus for manufacturing a display apparatus according to an embodiment;

FIG. 6 is a perspective view of a mask assembly according to an embodiment;

FIGS. 7 and 8 are schematic plan views of a second mask according to an embodiment;

FIG. 9 is a plan view of a second mask according to a comparative example;

FIG. 10 is a schematic cross-sectional view of a second mask according to an embodiment; and

FIGS. 11 to 19 are schematic views showing steps of a method of manufacturing a display apparatus according to an embodiment.

### DETAILED DESCRIPTION

Reference will now be made, in detail, to embodiments, examples of which are illustrated in the accompanying drawings. The described embodiments may have different forms and should not be construed as being limited to the descriptions set forth herein. Accordingly, the embodiments are merely described below, by referring to the figures, to explain aspects and features of the present disclosure.

Because the present disclosure allows for various changes and numerous embodiments, certain embodiments will be illustrated in the drawings and described in the written description. Aspects and features of the present disclosure, and methods for achieving them, will be described with reference to embodiments described below, in detail, with reference to the drawings. However, the present disclosure is not limited to the following embodiments and may be embodied in various forms.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

An X-axis, a Y-axis, and a Z-axis as used herein are not limited to three axes of the rectangular coordinate system and may be interpreted in a broader sense. For example, the X-axis, the Y-axis, and the Z-axis may be perpendicular to one another or may represent different directions that are not perpendicular to one another.

When a certain embodiment may be implemented differently, a specific process order may be performed in the order different from the described order. As an example, two processes successively described may be concurrently (or simultaneously) performed substantially and performed in the opposite order.

Hereinafter, embodiments of the present disclosure will be described with reference to the accompanying drawings.

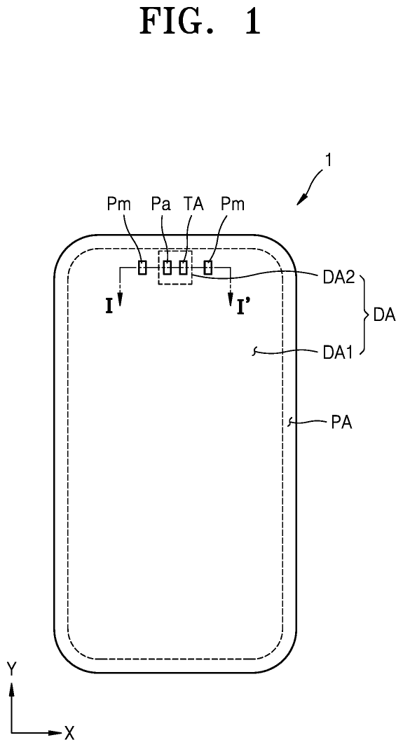

FIG. 1 is a schematic perspective view of a display apparatus 1 according to an embodiment.

The display apparatus 1, according to an embodiment, is applicable to various products, such as televisions (TVs), notebook computers, monitors, advertisement boards, and Internet of Things (IoT) devices, as well as to portable apparatuses, such as mobile phones, smartphones, tablet personal computers (PCs), mobile communication terminals, electronic organizers, electronic books, portable multimedia players (PMPs), navigation devices, and ultra mobile personal computers (UMPCs). In addition, the display apparatus 1, according to an embodiment, is applicable to wearable devices, such as smartwatches, watchphones, glasses-type displays, and head-mounted displays (HMDs). In addition, in an embodiment, the display apparatus 1 is applicable to a display screen in instrument panels for automobiles, center fascias for automobiles, or center information displays (CIDs) arranged on a dashboard, room (or interior) mirror displays that replace side mirrors of automobiles, and displays of an entertainment system arranged on the backside of front seats for backseat passengers in automobiles. For convenience of description, FIG. 1 shows the display apparatus 1 is used in a smartphone.

Referring to FIG. 1, the display apparatus 1 may have a display area DA and a peripheral area PA outside the display area DA. The display apparatus 1 may be configured to display images through a plurality of pixels arranged in a two-dimensional array in the display area DA.

The peripheral area PA is a region configured not to display images and may entirely surround (e.g., may entirely surround in a plan view or may extend entirely around a periphery of) the display area DA. Drivers may be arranged in the peripheral area PA, and the drivers may be configured to provide electrical signals or power to display elements arranged in the display area DA. A pad may be arranged in the peripheral area PA, and the pad may be a region to which electronic elements or a printed circuit board may be electrically connected.

The display area DA may have a first display area DA1 and a second display area DA2. Main sub-pixels Pm may be arranged in the first display area DA1, and auxiliary sub-pixels Pa may be arranged in the second display area DA2. The display apparatus 1 may be configured to display images by using light emitted from the main sub-pixels Pm arranged in the first display area DA1 and to display auxiliary images by using light emitted from the auxiliary sub-pixels Pa arranged in the second display area DA2.

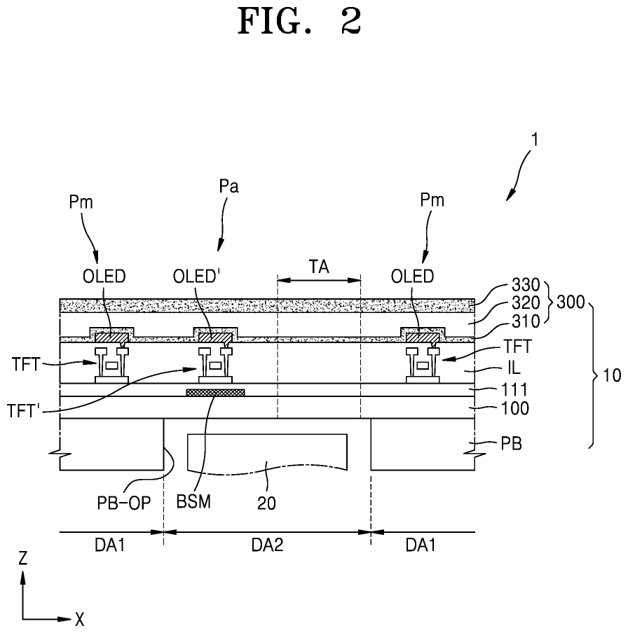

The second display area DA2 may be a region below (or under) which a component 20 (see, e.g., FIG. 2), such as a sensor that uses (e.g., is configured to receive and/or emit) an infrared ray, visible light, or sounds and the like is disposed as described below with reference to FIG. 2. The second display area DA2 may have a transmissive area TA through which light and/or sound that is output from the component 20 to the outside or that progresses toward the component 20 from the outside may pass. In an embodiment, a light transmittance of the second display area DA2 may be about 30% or more, about 50% or more, about 75% or more, about 80% or more, about 85% or more, or about 90% or more.

An image displayed in the second display area DA2 is an auxiliary image, and the resolution of the auxiliary image may be less than the resolution of an image displayed in the first display area DA1. For example, because the second display area DA2 includes the transmissive area TA through which light and/or sound may pass, the number of auxiliary sub-pixels Pa arranged per unit area in the second display area DA2 may be less than the number of main sub-pixels Pm arranged per unit area in the first display area DA1.

In an embodiment, the second display area DA2 may be arranged on one side of the first display area DA1. FIG. 1 shows an embodiment in which the second display area DA2 is arranged on the central top side of the first display area DA1 and is partially surrounded by the first display area DA1. However, the present disclosure is not limited thereto. In another embodiment, the second display area DA2 may be arranged on the left or right of the first display area DA1, and the second display area DA2 may be arranged between the peripheral area PA and the first display area DA1.

Hereinafter, although the display apparatus 1 is described as being an organic light-emitting display apparatus, the display apparatus 1 is not limited thereto. In other embodiments, various types of display apparatuses, such as inorganic light-emitting display apparatuses, quantum dot light-emitting display apparatuses, etc. may be used as the display apparatus 1.

FIG. 2 is a schematic cross-sectional view of the display apparatus 1 taken along the line I-I′ of FIG. 1 according to an embodiment.

Referring to FIG. 2, the display apparatus 1 may include a display panel 10 including display elements and the component 20 overlapping (e.g., under or below) the display panel 10. In the illustrated embodiment, the component 20 is disposed below the display panel 10 and is arranged in the second display area DA2.

The display panel 10 may include a substrate 100, transistors TFT and TFT′ disposed on the substrate 100, the display elements (e.g., organic light-emitting diodes OLED and OLED′) electrically connected to the transistors TFT and TFT′, and an encapsulation layer 300 covering the display elements. The display panel 10 may further include a lower protective film PB disposed under the substrate 100.

The substrate 100 may include glass or a polymer resin. The substrate 100 including the polymer resin may be flexible, foldable, rollable, or bendable. The substrate 100 may have a multi-layered structure including a polymer resin layer and an inorganic layer.

The transistors TFT and TFT′ and the organic light-emitting diodes OLED and OLED′, as the display elements that are electrically connected to the transistors TFT and TFT′, may be disposed on the substrate 100. The organic light-emitting diodes OLED and OLED′ may be configured to emit red, green, and blue light.

The main sub-pixel Pm may be arranged in the first display area DA1, and the main sub-pixel Pm includes the main transistor TFT and the main organic light-emitting diode OLED connected thereto. The auxiliary sub-pixel Pa may be arranged in the second display area DA2, and the auxiliary sub-pixel Pa includes the auxiliary transistor TFT′ and the auxiliary organic light-emitting diode OLED′ connected thereto.

The transmissive area TA may be located in the second display area DA2. The transmissive area TA may be a region through which light emitted from the component 20 and/or light directed to the component 20 may pass. In the display panel 10, a transmittance of the transmissive area TA may be about 30% or more, about 40% or more, about 50% or more, about 60% or more, about 70% or more, about 75% or more, about 80% or more, about 85% or more, or about 90% or more.

The component 20 may include a sensor, such as a proximity sensor, an illuminance sensor, an iris sensor, and a face recognition sensor, and/or a camera (or an image sensor). The component 20 may use light. As an example, the component 20 may be configured to emit and/or receive light in the infrared, ultraviolet, and/or visible light bands. A proximity sensor that uses an infrared ray (e.g., infrared light) may detect an object arranged close to the upper surface of the display apparatus 1, and an illuminance sensor may detect brightness of light incident to the upper surface of the display apparatus 1. In addition, an iris sensor may be configured to capture a person's iris arranged over the upper surface of the display apparatus 1, and a camera may be configured to receive light from an object arranged on the upper surface of the display apparatus 1.

In an embodiment, a buffer layer 111 and an insulating layer IL may be disposed between the substrate 100 and the organic light-emitting diodes OLED and OLED′. The insulating layer IL may include a plurality of inorganic insulating layers and/or a plurality of organic insulating layers.

A bottom electrode layer BSM may be disposed between the substrate 100 and the buffer layer 111 to prevent deterioration of the auxiliary transistor TFT arranged in the second display area DA2 due to light passing through the transmissive area TA. The bottom electrode layer BSM may be arranged to correspond to a lower portion of the auxiliary transistor TFT′. The bottom electrode layer BSM may be configured to block external light from reaching the auxiliary sub-pixel Pa including the auxiliary transistor TFT′ and the like. As an example, when light is emitted from the component 20, the bottom electrode BSM may be configured to block the light from reaching the auxiliary sub-pixel Pa. In an embodiment, because a constant voltage or a signal may be applied to the bottom electrode layer BSM, damage to a pixel circuit due to electrostatic discharge may be mitigated or prevented.

The bottom electrode layer BSM may be arranged in the second display area DA2 and may have an opening overlapping the transmissive area TA. Accordingly, the bottom electrode layer BSM may not be arranged in the transmissive area TA. In addition, the bottom electrode layer BSM may not be arranged in the first display area DA1.

The encapsulation layer 300 may cover the organic light-emitting diodes OLED and OLED′. The encapsulation layer 300 may include at least one inorganic layer and at least one organic layer. In an embodiment, the encapsulation layer 300 may include a first inorganic layer, a second inorganic layer, and an organic layer therebetween.

First and second inorganic layers 310 and 330 may include at least one inorganic insulating material from among aluminum oxide, titanium oxide, tantalum oxide, hafnium oxide, zinc oxide, silicon oxide, silicon nitride, silicon oxynitride, and the like. The organic layer 320 may include a polymer-based material. The polymer-based material may include an acryl-based resin, an epoxy-based resin, polyimide, and polyethylene.

The lower protective film PB may be attached under the substrate 100 to support and protect the substrate 100. The lower protective film PB may have an opening PB-OP corresponding to (e.g., aligned with) the second display area DA2. Because the opening PB-OP is provided in the lower protective film PB, light transmittance of the second display area DA2 may be improved. The lower protective film PB may include polyethylene terephthalate (PET) or polyimide (PI).

The area of the second display area DA2 may be greater than an area at where the component 20 is arranged. Accordingly, the area of the opening PB-OP in the lower protective film PB may not coincide with (e.g., may not exactly coincide with) the area of the second display area DA2. As an example, the area of the opening PB-OP may be less than the area of the second display area DA2.

In addition, a plurality of components 20 may be arranged in the second display area DA2. The plurality of components 20 may be different from each other in function. As an example, one of the plurality of components 20 may be a camera and another thereof may be an infrared sensor.

An element, such as an input sensing member configured to sense a touch input, a polarizer, a retarder, and an anti-reflection member including color filters and a black matrix, and a transparent window may be further disposed on the display panel 10.

Although it is shown in FIG. 2 that the encapsulation layer 300 is used as an encapsulation member encapsulating the organic light-emitting diodes OLED and OLED′, the present disclosure is not limited thereto. As an example, a member attached to the substrate 100 by using a sealant or frit may be used as a member for sealing the organic light-emitting diodes OLED and OLED′.

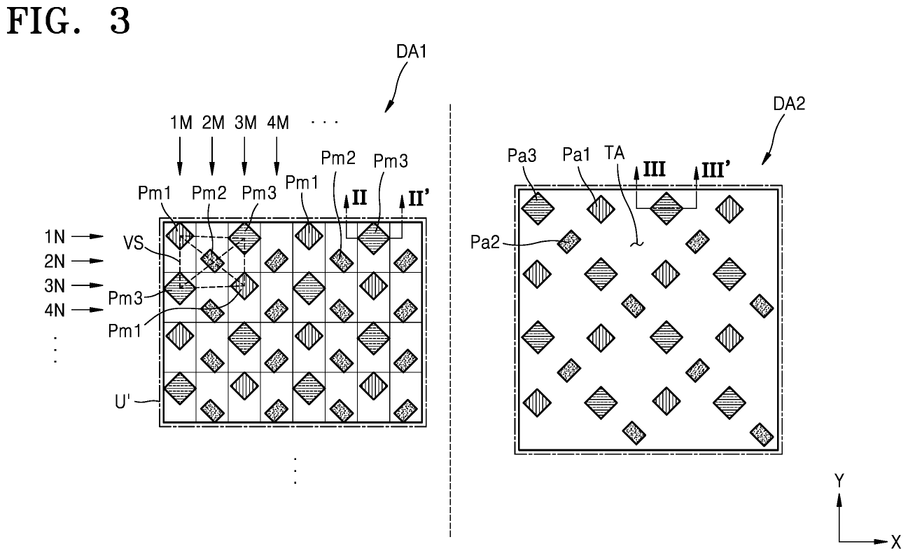

FIG. 3 is a schematic plan view of configuration of the sub-pixels and the transmissive area TA arranged in the first display area DA1 and the second display area DA2 of the display apparatus 1 according to an embodiment.

Referring to FIG. 3, main sub-pixels Pm1, Pm2, and Pm3 may be arranged in the first display area DA1 of the display apparatus 1 according to an embodiment, and auxiliary sub-pixels Pa1, Pa2, and Pa3 and the transmissive area TA may be arranged in the second display area DA2.

In an embodiment, the main sub-pixels Pm1, Pm2, and Pm3 arranged in the first display area DA1 and the auxiliary sub-pixels Pa1, Pa2, and Pa3 arranged in the second display area DA2 may be arranged in different structures (or arrangements). In the specification, a configuration structure of the pixels is described based on an emission area of each sub-pixel. In this case, the emission area of the sub-pixel may be defined by an opening in a pixel-defining layer, which is described below.

As shown in FIG. 3, the main sub-pixels Pm1, Pm2, and Pm3 arranged in the first display area DA1 may be arranged in a PENTILE© structure (a registered trademark of Samsung Display Co., Ltd.) (also referred to as a RGBG arrangement). A first main sub-pixel Pm1, a second main sub-pixel Pm2, and a third main sub-pixel Pm3 may be respectively configured to implement (e.g., emit) light of different colors. As an example, the first main sub-pixel Pm1, the second main sub-pixel Pm2, and the third main sub-pixel Pm3 may be configured to respectively implement light of red, green, and blue.

The first main sub-pixels Pm1 and the third main sub-pixels Pm3 may be alternately arranged in a first row 1N, the second main sub-pixels Pm2 may be apart from each other at a regular (e.g., present) interval in a second row 2N adjacent thereto, the third main sub-pixels Pm3 and the first main sub-pixels Pm1 may be alternately arranged in a third row 3N adjacent thereto, and the second main sub-pixels Pm2 may be apart from each other at a regular interval in a fourth row 4N adjacent thereto. This pixel configuration is repeated up to an N-th row. In such an embodiment, the number of the third main sub-pixels Pm3 and the first main sub-pixels Pm1 may be greater than the second main sub-pixel Pm2.

The first main sub-pixels Pm1 and the third main sub-pixels Pm3 in the first row 1N and the second main sub-pixels Pm2 in the second row 2N may be alternately arranged with each other. Accordingly, the first main sub-pixels Pm1 and the third main sub-pixels Pm3 may be alternately arranged in a first column 1M, the second main sub-pixels Pm2 may be apart from each other at a regular (e.g., preset) interval in a second column 2M adjacent thereto, the third main sub-pixels Pm3 and the first main sub-pixels Pm1 may be alternately arranged in a third column 3M adjacent thereto, and the second main sub-pixels Pm2 may be apart from each other at a regular interval in a fourth column 4M adjacent thereto. This pixel configuration is repeated up to an M-th column.

Such a pixel configuration structure may be expressed (or described) differently, in which: first main sub-pixels Pm1 may be respectively arranged at first and third vertices facing each other from among vertices of a virtual quadrangle VS with a second main sub-pixel Pm2 centered at the center of the virtual quadrangle VS, and third main sub-pixels Pm3 may be respectively arranged on second and fourth vertices 1, which are the final two vertexes of the virtual quadrangle VS. In such an embodiment, the virtual quadrangle VS may be variously changed to a rectangle, a rhombus, a square, and the like.

This pixel configuration structure is referred to as a PENTILE© matrix structure. By applying rendering, in which color is represented by sharing adjacent pixels, a higher resolution may be implemented by using a smaller number of pixels.

A plurality of auxiliary sub-pixels Pa may be arranged in the second display area DA2. A first auxiliary sub-pixel Pa1, a second auxiliary sub-pixel Pa2, and a third auxiliary sub-pixel Pa3 may be respectively configured to implement light of different colors. As an example, the first auxiliary sub-pixel Pa1, the second auxiliary sub-pixel Pa2, and the third auxiliary sub-pixel Pa3 may be configured to respectively implement light of red, green, and blue.

The number of auxiliary sub-pixels Pa arranged per unit area in the second display area DA2 may be less than the number of main sub-pixels Pm arranged per unit area in the first display area DA1. As an example, a ratio of the number of auxiliary sub-pixels Pa arranged per the same area to the number of main sub-pixels Pm arranged per same area may be 1:2, 1:4, 1:8, and 1:9.

The auxiliary sub-pixels Pa arranged in the second display area DA2 may be arranged in various shapes. Some of the auxiliary sub-pixels Pa may gather to form a pixel group and may be arranged in various shapes, such as the PENTILE© structure, a stripe structure, a mosaic configuration structure, a delta configuration structure, and the like within the pixel group.

A distance between the auxiliary sub-pixels Pa and a distance between the main sub-pixels Pm arranged in a pixel group may be equal to each other. In another embodiment, as shown in FIG. 3, the auxiliary sub-pixels Pa may be dispersed in the second display area DA2. That is, a distance between adjacent ones of the auxiliary sub-pixels Pa may be greater than a distance between adjacent ones of the main sub-pixels Pm. A region of the second display area DA2 in which the auxiliary sub-pixels Pa are not arranged may be a region in which the display elements are not arranged and may be the transmissive area TA. Thus, the light transmittance of the second display area DA2 is relatively high.

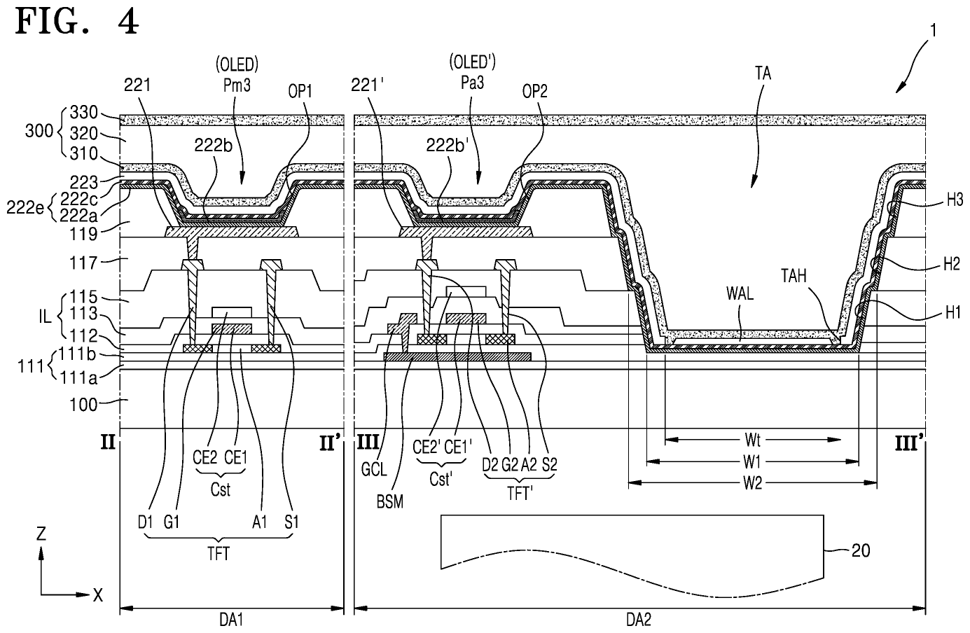

FIG. 4 is a schematic cross-sectional view of the display apparatus 1 taken along the lines II-II′ and III-III′ of FIG. 3 according to an embodiment.

FIG. 4 shows an embodiment in which the third main sub-pixel Pm3 is arranged in the first display area DA1, and the third auxiliary sub-pixel Pa3 and the transmissive area TA are arranged in the second display area DA2. In this embodiment, the third main sub-pixel Pm3 and the third auxiliary sub-pixel Pa3 may be sub-pixels configured to emit light of the same color. As an example, the third main sub-pixel Pm3 and the third auxiliary sub-pixel Pa3 may be sub-pixels configured to emit blue light.

The main sub-pixel Pm may include a main transistor TFT, a main storage capacitor Cst, and a main organic light-emitting diode OLED. The auxiliary sub-pixel Pa may include an auxiliary transistor TFT′, an auxiliary storage capacitor Cst′, and an auxiliary organic light-emitting diode OLED′. The transmissive area TA may have an opening area TAH.

The component 20 may be disposed in the second display area DA2. The component 20 may be a camera configured to capture an image or an infrared sensor configured to transmit/receive an infrared ray.

Because the transmissive area TA is provided in the second display area DA2, light transmitted/received from/to the component 20 may pass through the transmissive area TA. As an example, light emitted from the component 20 may progress in a +Z direction through the transmissive area TA, and light from the outside of the display apparatus 1 and incident to the component 20 may progress in a −Z direction through the transmissive area TA.

Hereinafter, a structure in which the elements of the display apparatus 1 according to an embodiment are stacked is described below.

The substrate 100 may include glass or a polymer resin. The polymer resin may include polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including the polymer resin may be flexible, rollable, or bendable. The substrate 100 may have a multi-layered structure including a polymer resin layer and an inorganic layer.

The buffer layer 111 may be disposed on the substrate 100 to reduce or block penetration of foreign materials, moisture, or external air from below the substrate 100 and to provide a flat surface on (e.g., to planarize) the substrate 100. The buffer layer 111 may include an inorganic material, an organic material, or an organic/inorganic composite material and may include a single layer or a multi-layer structure including an inorganic material including oxide or nitride and an organic material. A barrier layer may be further disposed between the substrate 100 and the buffer layer 111 to block penetration of external air. In an embodiment, the buffer layer 111 may include silicon oxide (SiOₓ) or silicon nitride (SiNₓ). The buffer layer 111 may include a first buffer layer 111a and a second buffer layer 111b that are stacked.

The bottom electrode layer BSM may be disposed between the first buffer layer 111a and the second buffer layer 111b in the second display area DA2. In another embodiment, the bottom electrode layer BSM may be disposed between the substrate 100 and the first buffer layer 111a. The bottom electrode layer BSM may be disposed under the auxiliary transistor TFT′ to prevent the characteristics of the auxiliary transistor TFT′ from being deteriorated by light emitted from the component 20.

In addition, the bottom electrode layer BSM may be connected to aline GCL disposed on a different layer through a contact hole (e.g., contact opening) and may be configured to receive a constant voltage or a signal from the line GCL. As an example, the bottom electrode layer BSM may be configured to receive a driving voltage or a scan signal. Because the bottom electrode layer BSM is configured to receive a constant voltage or a signal, a probability of electrostatic discharge occurring therein may be substantially reduced. The bottom metal layer BSM may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The bottom electrode layer BSM may have a single layer or a multi-layer structure of the above materials.

The main transistor TFT and the auxiliary transistor TFT′ may be disposed on the buffer layer 111. The main transistor TFT may include a first semiconductor layer A1, a first gate electrode G1, a first source electrode S1, and a first drain electrode D1, and the auxiliary transistor TFT′ may include a second semiconductor layer A2, a second gate electrode G2, a second source electrode S2, and a second drain electrode D2. The main transistor TFT may be connected to the main organic light-emitting diode OLED in the first display area DA1 to drive the main organic light-emitting diode OLED. The auxiliary transistor TFT′ may be connected to the auxiliary organic light-emitting diode OLED′ in the second display area DA2 to drive the auxiliary organic light-emitting diode OLED′.

The first semiconductor layer A1 and the second semiconductor layer A2 may be disposed on the buffer layer 111 and may include polycrystalline silicon. In another embodiment, the first semiconductor layer A1 and the second semiconductor layer A2 may include amorphous silicon. As an example, the first semiconductor layer A1 and the second semiconductor layer A2 may include an oxide of at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). Each of the first semiconductor layer A1 and the second semiconductor layer A2 may have a channel region and a source region and a drain region doped with impurities.

The second semiconductor layer A2 of the auxiliary transistor TFT′ may overlap the bottom electrode layer BSM with the second buffer layer 111b therebetween. In an embodiment, the width of the second semiconductor layer A2 may be less than the width of the bottom electrode layer BSM, and accordingly, the second semiconductor layer A2 may entirely overlap the bottom electrode layer BSM in a direction perpendicular to the substrate 100.

A first gate insulating layer 112 may be provided to cover the first semiconductor layer A1 and the second semiconductor layer A2. The first gate insulating layer 112 may include an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (e.g., ZnO₂). The first gate insulating layer 112 may include a single layer or a multi-layer structure including the inorganic insulating material.

The first gate electrode G1 and the second gate electrode G2 may be disposed on the first gate insulating layer 112 to respectively overlap the first semiconductor layer A1 and the second semiconductor layer A2. The first gate electrode G1 and the second gate electrode G2 may include at least one of molybdenum (Mo), aluminum (Al), copper (Cu), titanium (Ti) and the like and may be a single layer or a multi-layer structure. In an embodiment, the first gate electrode G1 and the second gate electrode G2 may each include a single layer of molybdenum (Mo).

A second gate insulating layer 113 may be provided to cover the first gate electrode G1 and the second gate electrode G2. The second gate insulating layer 113 may include an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (e.g., ZnO₂). The second gate insulating layer 113 may be a single layer or a multi-layer structure including the inorganic insulating material.

A first upper electrode CE2 of the main storage capacitor Cst and a second upper electrode CE2 of the auxiliary storage capacitor Cst′ may be disposed on the second gate insulating layer 113.

The first upper electrode CE2 may overlap the first gate electrode G1 disposed therebelow in the first display area DA1. The first gate electrode G1 and the first upper electrode CE2 overlap each other with the second gate insulating layer 113 therebetween to constitute the main storage capacitor Cst. That is, the first gate electrode G1 may act as the first lower electrode CE1 of the main storage capacitor Cst. However, the present disclosure is not limited thereto. The first lower electrode CE1 and the first gate electrode G1 may be spaced apart from each other and provided as separate elements.

The second upper electrode CE2′ may overlap the second gate electrode G2 disposed therebelow in the second display area DA2. The second gate electrode G2 and the second upper electrode CE2′ overlap each other with the second gate insulating layer 113 therebetween to constitute the auxiliary storage capacitor Cst′. That is, the second gate electrode G2 may act as the second lower electrode CE1′ of the auxiliary storage capacitor Cst′. However, the present disclosure is not limited thereto. The second lower electrode CE1′ and the second gate electrode G2 may be spaced apart from each other and provided as separate elements.

The first upper electrode CE2 and the second upper electrode CE2′ may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu) and may be a single layer or a multi-layer structure including the above materials.

An interlayer insulating layer 115 may be provided to cover the first upper electrode CE2 and the second upper electrode CE2′. The interlayer insulating layer 115 may include silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (e.g., ZnO).

The first gate insulating layer 112, the second gate insulating layer 113, and the interlayer insulating layer 115 may be collectively referred to herein as inorganic insulating layers IL. A structure in which the inorganic insulating layers IL are stacked on the substrate 100 may have a transmittance of about 90% or more with respect to an infrared wavelength. As an example, light having a wavelength in a range from about 900 nm to about 1100 nm passing through the substrate 100 and the inorganic insulating layers IL may have a transmittance of about 90%.

The source electrodes S1 and S2 and the drain electrodes D1 and D2 may be disposed on the interlayer insulating layer 115. The source electrodes S1 and S2 and the drain electrodes D1 and D2 may each include a conductive material including molybdenum (Mo), aluminum (Al), copper (Cu), and titanium (Ti) and may be a single layer or a multi-layer structure including the above materials. In an embodiment, the source electrodes S1 and S2 and the drain electrodes D1 and D2 may have a multi-layered structure of Ti/Al/Ti.

A planarization layer 117 may be disposed to cover the source electrodes S1 and S2 and the drain electrodes D1 and D2. The planarization layer 117 may have a flat upper surface such that a main pixel electrode 221 and an auxiliary pixel electrode 221′ disposed on the planarization layer 117 are formed flat.

The planarization layer 117 may be a single layer or a multi-layer structure including an organic material. The planarization layer 117 may include a general-purpose polymer, such as benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The planarization layer 117 has a via-hole that exposes one of the first source electrode S1 and the first drain electrode D1 of the main transistor TFT. The main pixel electrode 221 may be electrically connected to the main transistor TFT by being in contact with the first source electrode S1 or the first drain electrode D1 through the via-hole.

The planarization layer 117 also has a via-hole that exposes one of the second source electrode S2 and the second drain electrode D2 of the auxiliary transistor TFT′. The auxiliary pixel electrode 221′ may be electrically connected to the auxiliary transistor TFT′ by being in contact with the second source electrode S2 or the second drain electrode D2 through the corresponding via-hole.

The main pixel electrode 221 and the auxiliary pixel electrode 221′ may include a conductive oxide, such as indium tin oxide (ITO), indium zinc oxide (IZO), zinc oxide (ZnO), indium oxide (e.g., In₂O₃), indium gallium oxide (IGO), or aluminum zinc oxide (AZO). In an embodiment, the main pixel electrode 221 and the auxiliary pixel electrode 221′ may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the main pixel electrode 221 and the auxiliary pixel electrode 221′ may further include a layer on/under the reflective layer and including ITO, IZO, ZnOₓ, or In₂O₃. As an example, the main pixel electrode 221 and the auxiliary pixel electrode 221′ may have a stack structure of ITO/Ag/ITO.

A pixel-defining layer 119 may cover the edges of each of the main pixel electrode 221 and the auxiliary pixel electrode 221′. The pixel-defining layer 119 may have a first opening OP1 and a second opening OP2 respectively overlapping the main pixel electrode 221 and the auxiliary pixel electrode 221′ and defining an emission area of a sub-pixel. The pixel-defining layer 119 may prevent arcs and the like from occurring at the edges of the main and auxiliary pixel electrodes 221 and 221′ by increasing a distance between the edges of the main and auxiliary pixel electrodes 221 and 221′ and an opposite electrode 223 over the main and auxiliary pixel electrodes 221 and 221′. The pixel-defining layer 119 may include an organic insulating material, such as polyamide, an acryl resin, benzocyclobutene, and hexamethyldisiloxane (HMDSO), and may be formed by spin coating and the like.

The planarization layer 117 and the pixel-defining layer 119 may have a transmittance of about 90% or more with respect to light in an infrared wavelength. As an example, light having a wavelength in a range from about 900 nm to about 1100 nm passing through the planarization layer 117 and the pixel-defining layer 119 may have a transmittance of about 90%.

A main intermediate layer and an auxiliary intermediate layer may be disposed in the first opening OP1 and the second opening OP2 in the pixel-defining layer 119 to respectively correspond to the main pixel electrode 221 and the auxiliary pixel electrode 221′. The main intermediate layer may include a main emission layer 222b, and the auxiliary intermediate layer may include an auxiliary emission layer 222b′. The main emission layer 222b and the auxiliary emission layer 222b′ may include a polymer material or a low molecular weight material and may be configured to emit red, green, blue, or white light.

The main intermediate layer and/or the auxiliary intermediate layer may include an organic functional layer 222e on and/or under the main emission layer 222b and the auxiliary emission layer 222b′. The organic functional layer 222e may include a first functional layer 222a and/or a second functional layer 222c. In other embodiments, the first functional layer 222a and/or the second functional layer 222c may be omitted.

The first functional layer 222a may be disposed under the main emission layer 222b and the auxiliary emission layer 222b′. In an embodiment, similar to the main emission layer 222b and the auxiliary emission layer 222b′, the first functional layer 222a may be disposed in the first opening OP1 and the second opening OP2 by being patterned to correspond to the first opening OP1 and the second opening OP2. In another embodiment, the first functional layer 222a may be arranged to cover the entire surface of the first display area DA1 and the second display area DA2. In another embodiment, the first functional layer 222a may be disposed in the first opening OP1 and the second opening OP2 by being patterned to correspond to the first opening OP1 and the second opening OP2 and may not be disposed in the transmissive area TA. In another embodiment, the first functional layer 222a may be arranged to shield the entire surface of the first display area DA1 and the second display area DA2 except the transmissive area TA. Hereinafter, for convenience of description, an embodiment in which the first functional layer 222a is arranged to cover the entire surface of the first display area DA1 and the second display area DA2 is described in detail.

The first functional layer 222a may be a single layer or a multi-layer structure including an organic material. The first functional layer 222a may be a hole transport layer (HTL) having a single layer structure. In another embodiment, the first functional layer 222a may include a hole injection layer (HIL) and an HTL. The first functional layer 222a may be integrally formed to correspond to the main sub-pixels Pm and the sub-pixels Pa included in the first display area DA1 and the second display area DA2. Accordingly, the first functional layer 222a may be arranged to correspond to the transmissive area TA.

The second functional layer 222c may be disposed on the main emission layer 222b and the auxiliary emission layer 222b′. In an embodiment, similar to the main emission layer 222b and the auxiliary emission layer 222b′, the second functional layer 222c may be disposed in the first opening OP1 and the second opening OP2 by being patterned to correspond to the first opening OP1 and the second opening OP2. In another embodiment, the second functional layer 222c may be arranged to cover the entire surface of the first display area DA1 and the second display area DA2. In another embodiment, the second functional layer 222c may be disposed in the first opening OP1 and the second opening OP2 by being patterned to correspond to the first opening OP1 and the second opening OP2 and may not be disposed in the transmissive area TA. In another embodiment, the second functional layer 222c may be arranged to shield the entire surface of the first display area DA1 and the second display area DA2 except the transmissive area TA. Hereinafter, for convenience of description, an embodiment in which the second functional layer 222c is arranged to cover the entire surface of the first display area DA1 and the second display area DA2 is described in detail.

The second functional layer 222c may be a single layer or a multi-layer structure including an organic material. The second functional layer 222c may include an electron transport layer (ETL) and/or an electron injection layer (EIL). The second functional layer 222c may be integrally formed to correspond to the main sub-pixels Pm and the auxiliary sub-pixels Pa included in the first display area DA1 and the second display area DA2. Accordingly, the second functional layer 222c may be arranged to correspond to the transmissive area TA.

The opposite electrode 223 may be disposed on the second functional layer 222c. The opposite electrode 223 may include a conductive material having a low work function. As an example, the opposite electrode 223 may include a (semi-)transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. In another embodiment, the opposite electrode 223 may further include a layer on the (semi-)transparent layer including ITO, IZO, ZnO, or In₂O₃. The opposite electrode 223 may be integrally formed to correspond to the main sub-pixels Pm and the auxiliary sub-pixels Pa included in the first display area DA1 and the second display area DA2.

The layers from the main pixel electrode 221 to the opposite electrode 223 formed in the first display area DA1 may constitute the main organic light-emitting diode OLED, and the layers from the auxiliary pixel electrode 221′ to the opposite electrode 223 formed in the second display area DA2 may constitute the auxiliary organic light-emitting diode OLED.

In an embodiment, the opposite electrode 223 may have the opening area TAH corresponding to the transmissive area TA. In such an embodiment, a weak adhesion layer (WAL) may be disposed in an opening corresponding to the transmissive area TA. For example, the weak adhesion layer WAL may be disposed on the second functional layer 222c in the transmissive area TA. The weak adhesion layer WAL may be formed to correspond to the transmissive area TA before the opposite electrode 223 is formed. Because the opposite electrode 223 has a weak adhesive force with respect to the weak adhesion layer WAL, the opposite electrode 223 may not be formed on the upper surface of the weak adhesion layer WAL. Accordingly, a light transmittance of the transmissive area TA may be improved. This is described in more detail below.

In an embodiment, the widths of the openings constituting the opening area TAH may be substantially the same. As an example, the width of the opening in the opposite electrode 223 may be substantially equal to the width of the opening TAH.

In addition, in an embodiment, the first functional layer 222a and the second functional layer 222c may be omitted. In such an embodiment, the opening of the opposite electrode 223 may be the opening area TAH.

In an embodiment, the inorganic insulating layer IL, the planarization layer 117, and the pixel-defining layer 119 may respectively have a first hole H1, a second hole H2, and a third hole H3 corresponding to the transmissive area TA.

When the opening area TAH corresponds to the transmissive area TA, it may indicate that the opening area TAH overlaps the transmissive area TA. In such an embodiment, the area of the opening area TAH may be less than the area of the first hole H1 formed in the inorganic insulating layer IL. In FIG. 4, an embodiment in which a width Wt of the opening area TAH is less than a width W1 of the first hole H1 is shown as an example. Here, the area of the opening area TAH and the area of the first hole H1 may be defined as the area of a smallest opening.

In an embodiment, the first functional layer 222a, the second functional layer 222c, and the opposite electrode 223 may be disposed on the lateral surface of the first hole H1, the second hole H2, and the third hole H3. In an embodiment, a slope of the lateral surface of the first hole H1, the second hole H2, and the third hole H3 with respect to the upper surface of the substrate 100 may be gentler than the slope of the lateral surface of the opening area TAH with respect to the upper surface of the substrate 100.

When the opening area TAH is formed, a member such as the opposite electrode 223 is absent from the transmissive area TA. Accordingly, a light transmittance of the transmissive area TA may be substantially increased.

The main organic light-emitting diode OLED and the auxiliary organic light-emitting diode OLED′ may be sealed by the encapsulation layer 300. The encapsulation layer 300 may be disposed on an opposite electrode 223. The encapsulation layer 300 may be configured to prevent external moisture or foreign materials from penetrating the main organic light-emitting diode OLED and the auxiliary organic light-emitting diode OLED′.

The encapsulation layer 300 may include at least one inorganic layer and at least one organic layer. FIG. 4 shows an embodiment where the encapsulation layer 300 includes a first inorganic layer 310, an organic layer 320, and a second inorganic layer 330 are stacked on each other. In an embodiment, the number of organic layers, the number of inorganic layers, and a stack sequence may be changed.

The first and second inorganic layers 310 and 330 may include at least one inorganic insulating material from among aluminum oxide, titanium oxide, tantalum oxide, hafnium oxide, zinc oxide, silicon oxide, silicon nitride, silicon oxynitride, and the like and may be formed by chemical vapor deposition (CVD). The organic layer 320 may include a polymer-based material. The polymer-based material may include a silicon-based resin, an acryl-based resin, an epoxy-based resin, polyimide, and polyethylene.

The first inorganic layer 310, the organic layer 320, and the second inorganic layer 330 may each be integrally formed to cover the first display area DA1 and the second display area DA2. Accordingly, the first inorganic layer 310, the organic layer 320, and the second inorganic layer 330 may be disposed inside the opening area TAH.

In another embodiment, the organic layer 320 may be integrally formed to cover the first display area DA1 and the second display area DA2 and may not present in the transmissive area TA. In other words, the organic layer 320 may have an opening corresponding to the transmissive area TA. In such an embodiment, the first inorganic layer 310 and the second inorganic layer 330 may be in contact with each other in the opening area TAH.

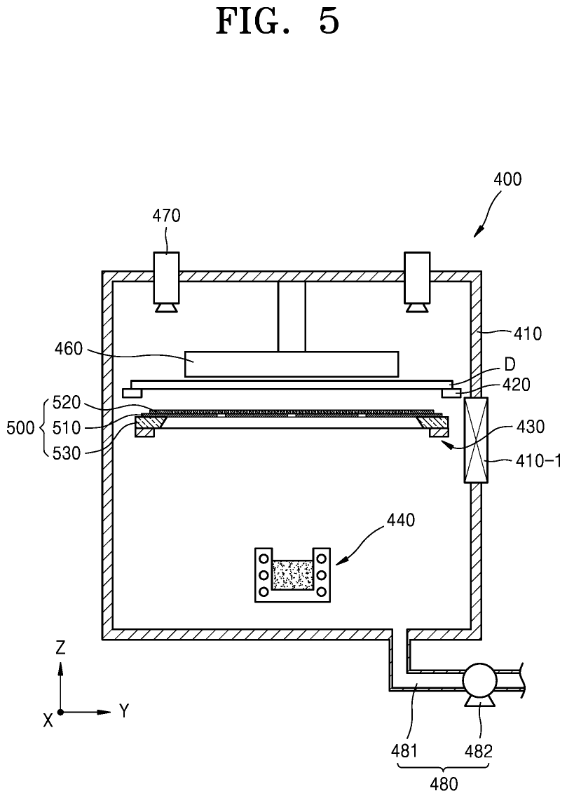

FIG. 5 is a cross-sectional view of an apparatus 400 for manufacturing a display apparatus according to an embodiment.

Referring to FIG. 5, the apparatus 400 for manufacturing a display apparatus may be used to manufacture the display apparatus 1 described above. The apparatus 400 for manufacturing the display apparatus 1 may include a chamber 410, a first supporter 420, a second supporter 430, a mask assembly 500, a deposition source 440, a magnetic force unit 460, a vision unit 470, and a pressure adjustor 480.

A space may be formed in the chamber 410, and a portion of the chamber 410 may be open. A gate valve 410-1 may be installed adjacent to the open portion of the chamber 410 such that the open portion of the chamber 410 may be opened or closed depending on (e.g., according to) an operation of the gate valve 410-1.

A first supporter 420 may seat (e.g., may receive) and support a display substrate D. The first supporter 420 may be a plate fixed inside the chamber 410. In another embodiment, the first supporter 420 may be a shuttle in which a display substrate D is seated and which is linearly movable inside the chamber 410. In another embodiment, the first supporter 420 may include an electrostatic chuck or an adhesive chuck disposed in the chamber 410 to be fixed or moveable up and down inside the chamber 410. Hereinafter, for convenience of description, an embodiment in which the first supporter 420 has a plate shape fixed inside the chamber 410 is mainly described in detail.

The mask assembly 500 may be seated on the second supporter 430. The second supporter 430 may be disposed inside the chamber 410. The second supporter 430 may be configured to fine-adjust the position of the mask assembly 500. To this end, the second supporter 430 may separately include a driver, an alignment unit, or the like to move the mask assembly 500 in different directions.

In another embodiment, the second supporter 430 may be a shuttle. In such an embodiment, the mask assembly 500 may be seated on the second supporter 430. The second supporter 430 may be configured to transfer the mask assembly 500. As an example, the second supporter 430 may move to the outside of the chamber 410, and after the mask assembly 500 is seated on the second supporter 430, the second supporter 430 may enter the chamber 410 from the outside of the chamber 410.

The first supporter 420 may be integrally formed with the second supporter 430, and the first supporter 420 and the second supporter 430 may include a movable shuttle. The first supporter 420 and the second supporter 430 may include a structure configured to fix the mask assembly 500 to the display substrate D with the display substrate D seated on the mask assembly 500 and may be configured to linearly move the display substrate D and the mask assembly 500 concurrently (or simultaneously).

Hereinafter, for convenience of description, an embodiment in which the first supporter 420 and the second supporter 430 are separate from each other and arranged in different positions and are arranged inside the chamber 410 is described in detail.

The deposition source 440 may be disposed to face the mask assembly 500. A deposition material may be received in the deposition source 440. The deposition material may be evaporated or sublimated by applying heat to the deposition material. The deposition source 440 may be fixed inside the chamber 410 or may be disposed inside the chamber 410 to be linearly moveable in one direction. Hereinafter, for convenience of description, an embodiment in which the deposition source 440 is disposed to be fixed inside the chamber 410 is described in detail.

The mask assembly 500 may include a mask frame 530, a first mask 510, and a second mask 520.

The magnetic force unit 460 may be disposed inside the chamber 410 to face the substrate D. The magnetic force unit 460 may apply a magnetic force to the mask assembly 500 to press (or pull) the mask assembly 500 toward the display substrate D. For example, the magnetic force unit 460 may not only prevent sagging of the first and second masks 510 and 520 but may also allow the first and second masks 510 and 520 to be adjacent to (e.g., to be closely arranged to) the display substrate D. In addition, the magnetic force unit 460 may be configured to maintain a uniform interval (or spacing) between the first and second masks 510 and 520 and the display substrate D.

The vision unit 470 may be disposed in the chamber 410 and may capture (e.g., may determine) the positions of the display substrate D and the mask assembly 500. The vision unit 470 may include a camera configured to capture (e.g., to view) the display substrate D and the mask assembly 500. The positions of the display substrate D and the mask assembly 500 may be identified (or determined) based on the image captured by the vision unit 470, and the position of the display substrate D may be fine-adjusted by the first supporter 420 and/or the position of the mask assembly 500 may be fine-adjusted by the second supporter 430. Hereinafter, an embodiment in which the second supporter 430 is configured to fine-adjust the position of the mask assembly 500 to align the positions of the display substrate D and the mask assembly 500 is described in detail.

The pressure adjustor 480 may be connected to the chamber 410 and configured to adjust the inner pressure of the chamber 410. As an example, the pressure adjustor 480 may be configured to adjust the inner pressure of the chamber 410 to be equal to or similar to atmospheric pressure. In addition, the pressure adjustor 480 may be configured to adjust the inner pressure of the chamber 410 to be equal to or similar to a vacuum state.

The pressure adjustor 480 may include a connection pipe 481 and a pump 482. The connection pipe 481 is connected to the chamber 410, and the pump 482 is installed to the connection pipe 481. External air may be introduced through the connection pipe 481 or a gas inside the chamber 410 may be guided to the outside through the connection pipe 481 according to an operation of the pump 482.

The apparatus 400 for manufacturing the display apparatus may be used to manufacture the display apparatus 1. When the pressure adjustor 480 is configured to make the inside of the chamber 410 equal to or similar to atmospheric pressure, the gate valve 410-1 may operate to open the open portion of the chamber 410.

Then, the display substrate D may be loaded into the chamber 410 from the outside. The display substrate D may be loaded into the chamber 410 by various suitable methods. As an example, the display substrate D may be loaded into the chamber 410 from the outside of the chamber 410 by a robot arm disposed outside the chamber 410. In another embodiment, when the first supporter 420 is a shuttle, the first supporter 420 may be carried from the inside of the chamber 410 to the outside of the chamber 410. Then, the display substrate D may be seated on the first supporter 420 by a separate robot arm arranged outside the chamber 410, and the first supporter 420 may be loaded into the chamber 410 from the outside of the chamber 410. Hereinafter, for convenience of description, an embodiment in which the display substrate D is loaded into the chamber 410 from the outside of the chamber 410 by a robot arm disposed outside the chamber 410 is described in detail.

The mask assembly 500 may be disposed inside the chamber 410 as described above. In another embodiment, in the same or similar manner to the display substrate D, the mask assembly 500 may be loaded into the chamber 410 from the outside of the chamber 410. Hereinafter, for convenience of description, an embodiment in which only the display substrate D is loaded into the chamber 410 from the outside of the chamber 410 with the mask assembly 500 disposed inside the chamber 410 is described in detail.

In another embodiment, as described above, the first supporter 420 and the second supporter 430, as shuttles, fix the display substrate D and the mask assembly 500 and, then, may be configured to load the mask assembly 500 into the chamber 410 from the outside of the chamber 410.

When the display substrate D is loaded into the chamber 410, the display substrate D may be seated on the first supporter 420. The vision unit 470 may be configured to capture (or determine) the positions of the display substrate D and the mask assembly 500. For example, the vision unit 470 may be configured to capture a first alignment mark on the display substrate D and a second alignment mark on the mask assembly 500.

The positions of the display substrate D and the mask assembly 500 may be identified based on the captured first alignment mark and second alignment mark. In some embodiments, the apparatus 400 for manufacturing the display apparatus may include a controller (e.g., a separate controller) to determine the positions of the display substrate D and the mask assembly 500.

When the determination of the positions of the display substrate D and the mask assembly 500 is completed, the second supporter 430 may fine-adjust the position of the mask assembly 500.

Then, the deposition source 440 operates to supply the deposition material toward the mask assembly 500, and the deposition material passes through a plurality of openings in the first and second masks 510 and 520 to be deposited on the display substrate D. In this case, the pump 482 may maintain the pressure of the chamber 410 at a state equal to or similar to a vacuum by sucking in (e.g., removing) the gas inside the chamber 410 and discharging the gas to the outside.

The deposition material may pass through the opening arranged in the deposition region described above to be deposited on the display substrate D. The mask assembly 500 may be configured to provide the deposition region equal to or similar to the deposition region described above.

The above operations may be repeatedly performed on a plurality of display substrates D. In this case, when a deposition frequency for the plurality of display substrates D is equal to a reference (or predetermined or preset) frequency, the operation of the apparatus 400 for manufacturing the display apparatus stops and the mask assembly 500 may be drawn out of the chamber 410.

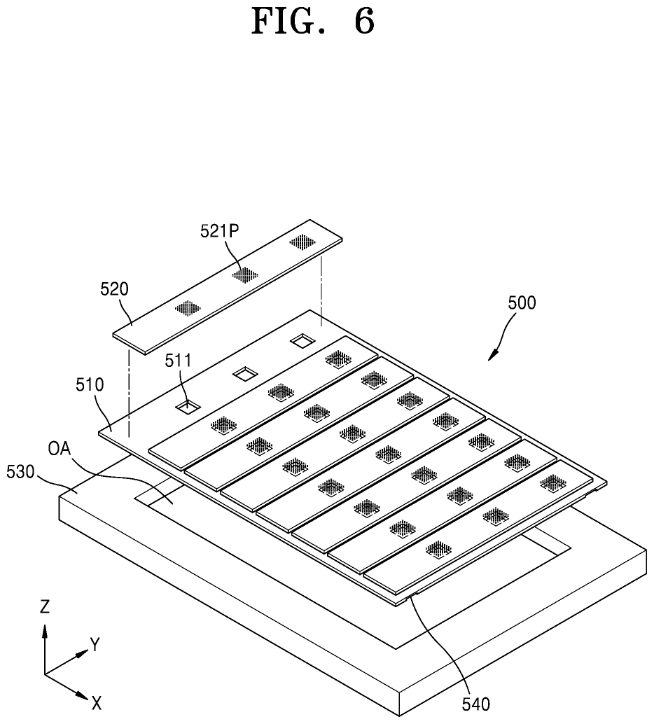

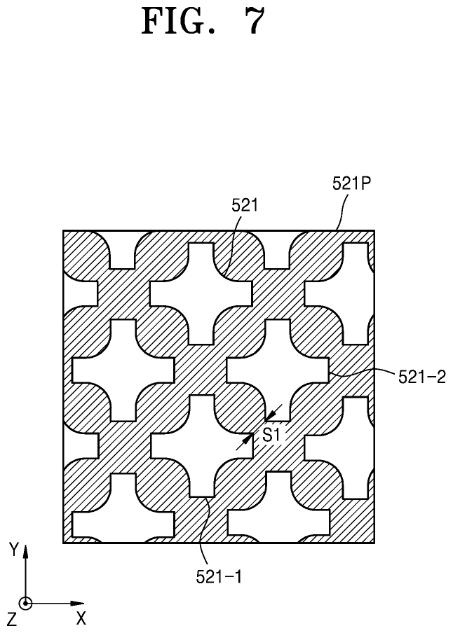

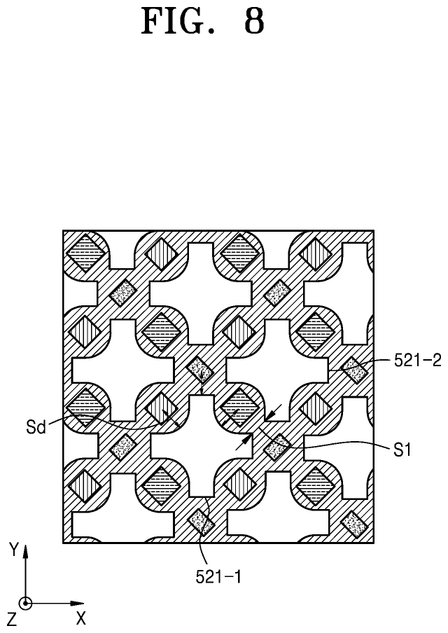

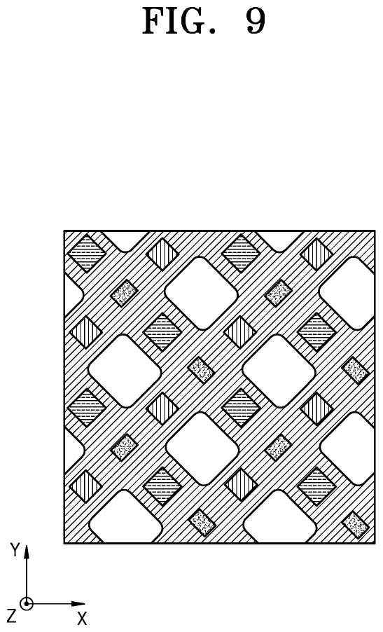

FIG. 6 is a perspective view of the mask assembly 500 according to an embodiment. FIGS. 7 and 8 are schematic plan views of the second mask 520 according to an embodiment. FIG. 7 shows an enlarged portion of an opening pattern 521P of the second mask 520, and FIG. 8 shows the auxiliary sub-pixel Pa disposed on the display substrate D together with the second mask 520. FIG. 9 is a plan view of the second mask 520 according to a comparative example.

Referring to FIG. 6, the mask assembly 500 may include the first mask 510, the second mask 520, and the mask frame 530.

The mask frame 530 may have an opening area OA in the center. In an embodiment, the mask frame 530 may have a quadrangular loop shape in which one opening area OA is formed in the center. In another embodiment, the mask frame 530 may be formed in a grid shape such as a window frame having a plurality of opening areas OA. Hereinafter, for convenience of description, an embodiment in which the mask frame 530 has one opening area OA in the center thereof is described in detail.

The first mask 510 may be disposed on the mask frame 530. For example, the first mask 510 may be arranged to cover (e.g., to extend over) the opening area OA of the mask frame 530. In an embodiment, the first mask 510 is formed greater than (e.g., larger than) the area of the opening area OA and may be disposed on the mask frame 530 to completely cover the opening area OA. In an embodiment, the first mask 510 may be fixed to the mask frame 530 by welding.

The first mask 510 may have first openings 511. The first openings 511 may be arranged at positions overlapping the opening area OA in the mask frame 530, that is, arranged inside of (or aligned with) the opening area OA in a plan view. In an embodiment, the first mask 510 may include at least one first opening 511. In another embodiment, the first mask 510 may include a plurality of first openings 511 spaced apart from each other. Hereinafter, for convenience of description, an embodiment in which the plurality of first openings 511 is provided is described.

In an embodiment, the first mask 510 may be a mask configured to deposit a deposition material on the display substrate D. The display substrate D may be a portion of the display apparatus being manufactured. As an example, the display substrate D may denote a state in which some of a plurality of layers are stacked on the substrate 100 of the display panel 10. In an embodiment, the display substrate D is a mother substrate and may include a plurality of cells. The plurality of cells may be cut apart to form a plurality of display panels 10. For example, the plurality of display panels 10 may be manufactured by depositing the deposition materials on the plurality of cells of the display substrate D and then cutting the display substrate D along the plurality of cells.

In an embodiment, the first opening 511 may be formed in the first mask 510 to correspond to the second display area DA2 (see, e.g., FIG. 1) of the display panel 10. Each of the plurality of first openings 511 may be formed at a position corresponding to the second display area DA2 in the plurality of cells of the display substrate D. The size of the first opening 511 may be equal or similar to the size of the second display area DA2 (see, e.g., FIG. 1).

In an embodiment, although the first opening 511 may be formed in a quadrangular shape to correspond to the second display area DA2 (see, e.g., FIG. 1), the present disclosure is not limited thereto. The first opening 511 may be formed in a circular shape, a polygonal shape, a star shape, or an irregular shape according to the shape of the second display area DA2.

The second mask 520 may be disposed on the first mask 510. For example, the second mask 520 may be disposed on the first mask 510 opposite the mask frame 530. The second mask 520 may be disposed to cover the first mask 510, for example, the first opening(s) 511. In an embodiment, at least two second masks 520 may be provided. When two or more second masks 520 are provided, the second masks 520 may be arranged to be parallel to each other. In such an embodiment, the second masks 520 may be arranged in one direction (e.g., the X direction in FIG. 6). In an embodiment, the second mask 520 may be fixed to the first mask 510 by welding.

The second mask 520 may have an opening pattern 521P. In an embodiment, at least one opening pattern 521P may be provided. The number of opening patterns 521P may correspond to the number of first openings 511. In a plan view, the opening pattern 521P may be arranged to overlap (e.g., to be aligned with) the first opening 511. For example, the opening pattern 521P may be disposed on (or over) the first opening 511. In addition, the shape of the circumference of the opening pattern 521P may correspond to the shape of the first opening 511. As an example, when the first opening 511 is a quadrangular shape, the opening pattern 521P may be the quadrangular shape having the same size.

Referring to FIGS. 6 to 8, the opening pattern 521P may include a plurality of second openings 521. Accordingly, a plurality of second openings 521 may be formed in a region of the second mask 520 corresponding to the first opening 511. For example, each of the plurality of second openings 521 may be formed to overlap the inside of the first opening 511 when viewed in a direction (e.g., the Z direction in FIG. 6) perpendicular to one surface of the first mask 510. In other words, the plurality of second openings 521 may overlap each other in (or over) the first opening 511. The diameter or the area (e.g., the diameter or the area of the cross-section of the second opening in the plan view of FIG. 6) of the second opening 521 may be less than the diameter or the area of the first opening 511.

In an embodiment, each of the plurality of second openings 521 may be formed at a position corresponding to the transmissive area TA (see, e.g., FIG. 3) of the second display area DA2 (see, e.g., FIG. 1). The size of the second opening 521 may be equal to or similar to the size of the transmissive area TA. In another embodiment, the second opening 521 may overlap the transmissive area TA. Accordingly, when depositing the deposition material, the deposition material may sequentially pass through the opening area OA in the mask frame 530, the first opening 511 in the first mask 510, and the second opening 521 in the second mask 520 to be deposited on the transmissive area TA of the second display area DA2. In this case, the deposition material deposited in the transmissive area TA may form the weak adhesion layer WAL.

The second mask 520 may be a mask formed by using electro-forming. The opening pattern 521P in the second mask 520 may include (or may be formed by) a plurality of second openings 521.

In an embodiment, the second opening 521 may be spaced apart from the auxiliary sub-pixel Pa without overlapping the auxiliary sub-pixel Pa in a plan view. As an example, the second opening 521 may be arranged between the auxiliary sub-pixels Pa. In an embodiment, the second opening 521 is a quadrangle having four sides and may have a shape in which each side thereof is concave toward the center of the quadrangle. Because the second mask 520, according to an embodiment, is manufactured by using electro-forming, an opening having a more complicated shape may be easily formed.

Shortest distances between the second opening 521 and the auxiliary sub-pixels Pa adjacent to the second opening 521 may be the same. As an example, as shown in FIG. 8, the second opening 521 may be surrounded by eight auxiliary sub-pixels Pa adjacent to four sides and four vertexes. In this embodiment, shortest distances Sd between the auxiliary sub-pixels Pa and the second opening 521 may all be the same.

This may be implemented by manufacturing the second mask 520 by using electro-plating. Referring to FIG. 9, a comparative example of a mask manufactured by a general method is illustrated. As shown in FIG. 9, when using a general mask manufacturing method, it may be difficult to precisely form an opening. Accordingly, shortest distances between the opening and the auxiliary sub-pixels may be different from each other. That is, in the second mask 520 according to an embodiment, the opening may be formed to be maximally adjacent to the auxiliary sub-pixels Pa according to the configuration of the auxiliary sub-pixels Pa such that an aperture ratio may be improved.

In addition, in an embodiment, a manufacturing tolerance at one point of the circumference of the second opening 521 may be about ±1.5 μm or less. The manufacturing tolerance may be a numerical difference between a preset design drawing (or specification) and the second opening 521 that is actually manufactured. In addition, an average manufacturing tolerance of the second opening 521 may also be about ±1.5 μm or less. The average manufacturing tolerance denotes an average value of manufacturing tolerances at respective points along the circumference of the second opening 521. For example, the second opening 521 may be uniformly formed along the circumference and may be particularly uniformly formed without increasing manufacturing tolerance even at the corners and the like.

In an embodiment, the corner curvature radius of the second opening 521 may be about 6 μm or less or about 3 μm to about 6 μm. The corner curvature radius may be a curvature radius indicating a degree of roundness at the corner of the second opening 521. Because the second opening 521 may have a small corner curvature radius, even when an angle of the corner of the second opening 521 is small to form a relatively sharp corner, the corner may be precisely implemented.

In addition, a shortest distance S1 between two adjacent second openings 521 from among the plurality of second openings 521 may be about 10 μm or less or about 3 μm to about 10 μm. As an example, the second opening 521 may include a (2-1)st opening 521-1 and a (2-2)nd opening 521-2. A shortest distance between the (2-1)st opening 521-1 and the (2-2)nd opening 521-2 may be about 10 μm or less. The distance between the (2-1)st opening 521-1 and the (2-2)nd opening 521-2 may correspond to the width of a rib of the second mask 520. For example, the shortest distance between the (2-1)st opening 521-1 and the (2-2)nd opening 521-2 may denote a minimum width from among the widths of the rib of the second mask 520. Accordingly, because the area occupied by the second opening 521 may be reduced, the aperture ratio may be improved.

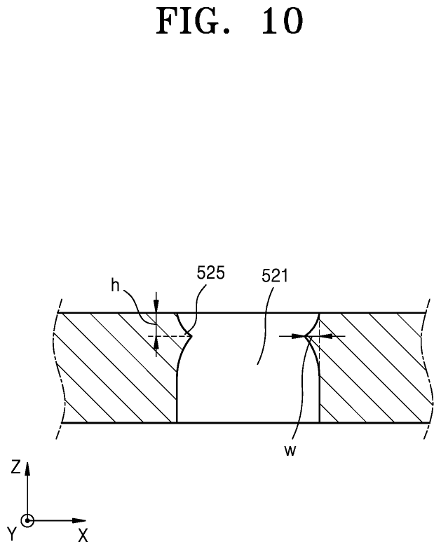

FIG. 10 is a schematic cross-sectional view of the second mask 520 according to an embodiment.

Referring to FIG. 10, the second mask 520 may further include a hump (or bump) 525. The hump 525 may be a protrusion protruding from the inner surface of the second mask 520 defining the second opening 521 toward the center of the opening. The hump 525 may be formed during the manufacturing process, and when the height and width of the hump 525 are small, a shadow phenomenon of the deposition material may be prevented.

In an embodiment, a height h of the hump 525 may be about 0.5 μm or less or in a range of about 0.2 μm to about 0.5 μm. The height h of the hump 525 may denote a length from one surface of the second mask 520 facing the display substrate D to the bump 525. In addition, in an embodiment, a width w of the bump 525 may be 1 μm or less or in a range of about 0.3 μm to about 1 μm. The width w of the hump 525 may denote a length protruding from the inner surface of the second mask 520 defining the second opening 521 to the bump 525. As described above, because the height h and the width w of the bump 525 are relatively very small, the second mask 520 may prevent a shadow phenomenon and the aperture ratio may be improved.

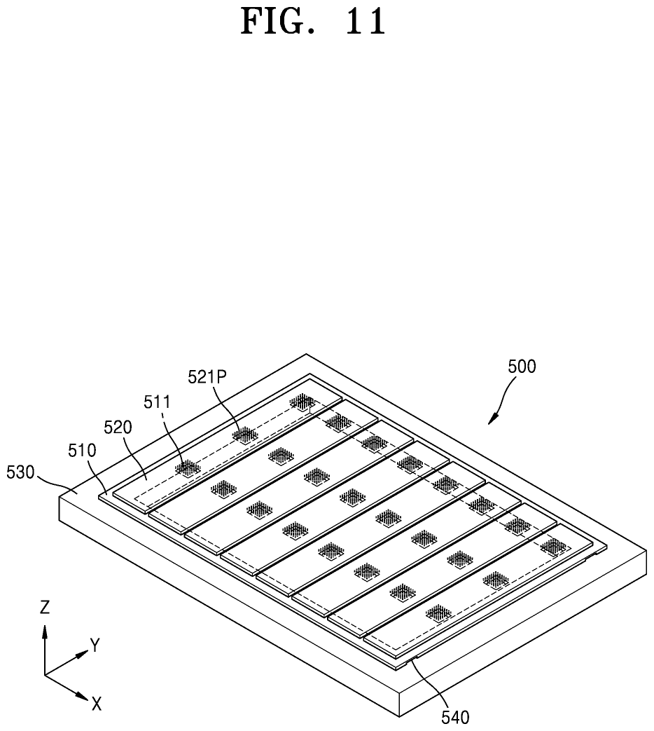

FIGS. 11 to 19 are schematic views showing steps of a method of manufacturing the display apparatus 1 according to an embodiment. The method of manufacturing the display apparatus 1 according to an embodiment may be used to manufacture the display apparatus 1 described above. In addition, the method of manufacturing the display apparatus 1 according to an embodiment may be configured to manufacture the display apparatus 1 by using the apparatus for manufacturing the display apparatus.

Referring to FIG. 11, the first mask 510 having the first opening 511 may be fixed to the mask frame 530 having the opening area OA. The first mask 510 may be fixed to the mask frame 530 while being tensioned. In an embodiment, the first mask 510 may be welded to the mask frame 530.

The second mask 520 having the opening pattern 521P may be disposed on the first mask 510. In an embodiment, the second mask 520 may be fixed to the first mask 510 while being tensioned. In an embodiment, the second mask 520 may be fixed to the first mask 510.

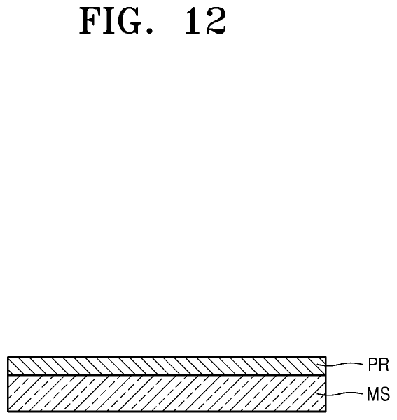

Referring to FIGS. 12 to 17, steps of a process of manufacturing the second mask 520 is described in more detail. In an embodiment, the second mask 520 may be manufactured by using electro-forming. The electro-forming is a method of making a metal shape by using electroplating.

Referring to FIG. 12, a photoresist PR may be formed on a mask substrate MS first. In an embodiment, the mask substrate MS may include stainless steel. One of a positive photoresist and a negative photoresist may be coated on the mask substrate MS. An exposed region is etched in the positive photoresist PR during a developing process. Conversely, when the negative photoresist PR is used, the rest of the area other than the exposed area is etched. Hereinafter, an embodiment in which the photoresist PR is a negative photoresist is described in detail.

The photoresist PR may be formed by coating photoresist solution on the mask substrate MS by using various suitable methods, such as spin-coating, spraying, or dipping.

In addition, a process of polishing the upper surface of the mask substrate MS on which the photoresist PR is to be coated may be additionally performed before the photoresist PR is coated on the mask substrate MS.

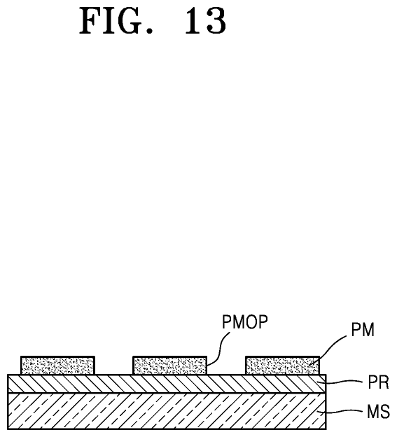

Next, referring to FIG. 13, an exposure mask PM is disposed on the photoresist PR, and at least a portion of the photoresist PR may be exposed therethrough. The exposure mask PM may have an exposure opening PMOP, and a portion of the photoresist PR corresponding to the exposure opening PMOP may be exposed through the exposure mask PM. The portion of the photoresist PR corresponding to the exposure opening PMOP may be a portion in which the second opening 521 of the second mask 520 is formed.

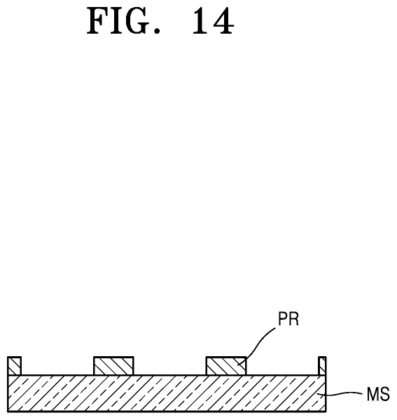

Next, referring to FIG. 14, the photoresist PR may be developed. Accordingly, a portion of the photoresist PR may be removed. When the photoresist PR uses the negative-type photoresist solution, when the developing process is performed, an unexposed region of the photoresist PR may be removed. Accordingly, a region corresponding to the exposure opening PMOP, that is, a region of the photoresist PR corresponding to the second opening 521 may remain on the mask substrate MS.

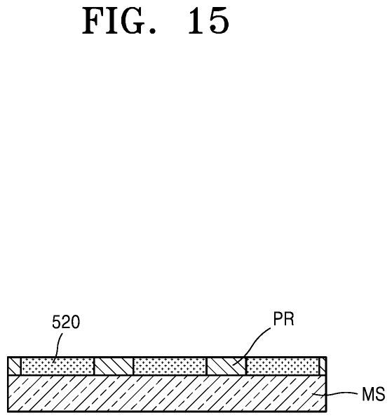

Next, referring to FIG. 15, the second mask 520 may be formed by using electro-forming. The second mask 520 may include stainless steel, invar, nickel (Ni), cobalt (Co), a nickel alloy, a nickel-cobalt alloy, or the like. That is, when the metal fills portions from which the photoresist PR is removed, the second mask 520 may be formed.

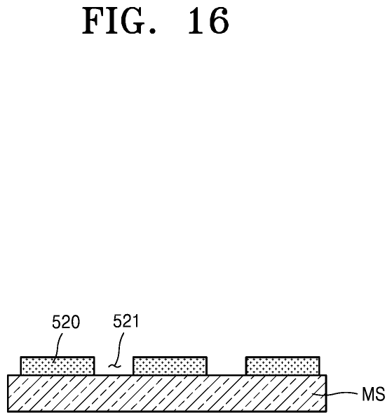

Next, referring to FIG. 16, the remaining photoresist PR may be removed. When the photoresist PR is removed, the second mask 520 with the second openings 521 may be formed.

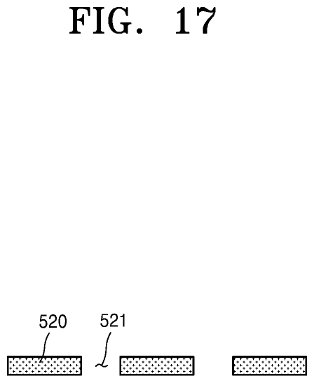

Next, referring to FIG. 17, the mask substrate MS is separated from the second mask 520, and the second mask 520 may be manufactured.

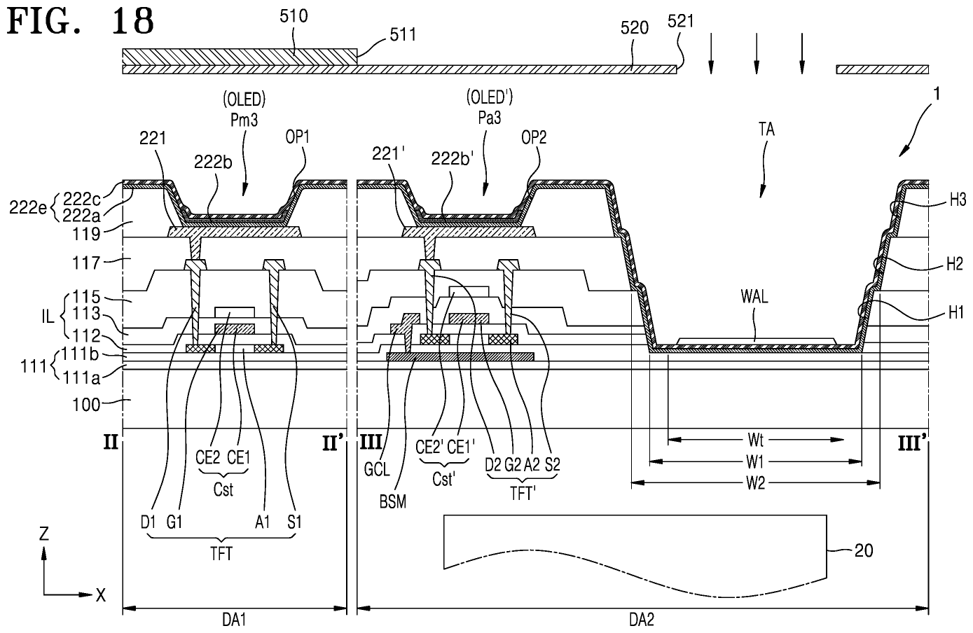

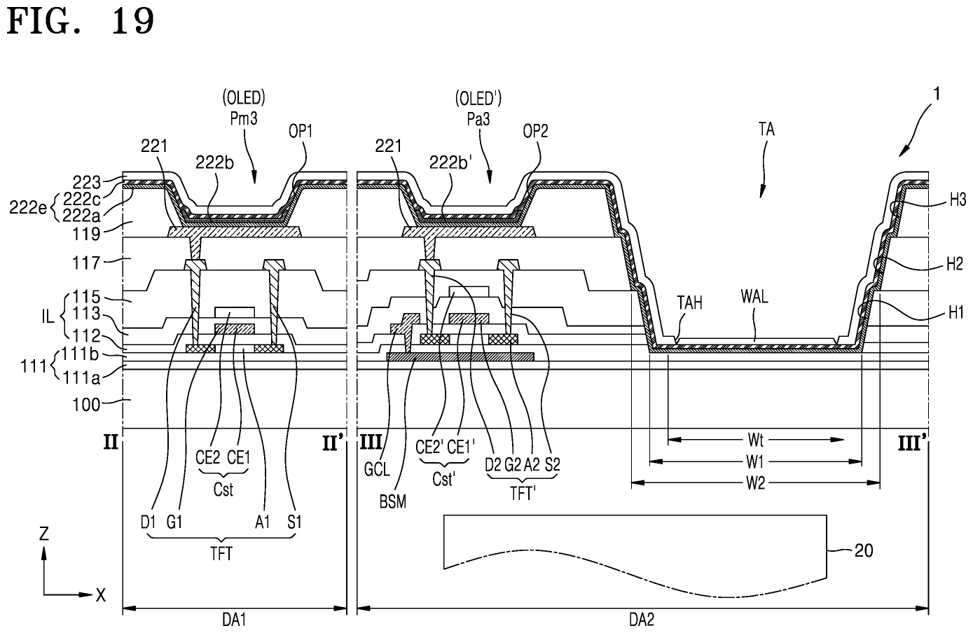

Referring to FIGS. 18 and 19, a process of forming the display apparatus 1, particularly, for forming the weak adhesion layer WAL by using the apparatus for manufacturing the display apparatus is described in more detail.

Referring to FIG. 18, the deposition material forming the opposite electrode 223 has a characteristic that a film formation result varies depending on a surface on which the deposition material is deposited. As an example, magnesium (Mg) from among materials for forming the opposite electrode 223 is difficult to form a film on an interface washed by a solvent, such as MeOH, and an interface between a hole injection layer HIL and a hole transport layer HTL. In addition, Mg is difficult to form a film also on a material forming the pixel-defining layer 119. This characteristic of Mg may be used as self-pattering technology of the opposite electrode 223.

Referring to FIG. 18, before the opposite electrode 223 is formed, the weak adhesion layer WAL is formed to correspond to the transmissive area TA. As an example, the weak adhesion layer WAL may form the upper surface of the second functional layer 222c inside the first hole H1 in the inorganic insulating layer IL.

The weak adhesion layer WAL may be formed to correspond to the transmissive area TA by using the mask assembly 500 including a region in which the first opening 511 in the first mask 510 overlaps the second opening 521 in the second mask 520. For example, the first opening 511 may be open to correspond to the second display area DA2, and the second opening 521 may be open to correspond to the transmission area TA. Thus, the deposition material for forming the weak adhesion layer WAL may pass through the opening area OA in the mask frame 530, the first opening 511 in the first mask 510, the second opening 521 in the second mask 520 to be formed in the transmissive area TA in the apparatus 400 for manufacturing the display apparatus.

The weak adhesion layer WAL is a material having weak adhesive force with respect to the opposite electrode 223. The weak adhesive layer WAL may be a material having a characteristic that the opposite electrode 223 is not formed or is formed very thin on the upper surface of the weak adhesion layer WAL.

As an example, the weak adhesion layer WAL may include 8-quinolinato lithium (Liq; [8-Quinolinolato Lithium]), N,N-diphenyl-N,N-bis(9-phenyl-9H-carbazol-3-yl) Biphenyl-4,4′-diamine (N, N-diphenyl-N, N-bis (9-phenyl-9H-carbazol-3-yl) biphenyl-4,4′-diamine; HT01), N (di Phenyl-4-yl) 9,9-dimethyl-N-(4 (9-phenyl-9H-carbazol-3-yl) phenyl)-9H-fluoren-2-amine (N (diphenyl-4-yl) 9,9-dimethyl-N-(4(9-phenyl-9H-carbazol-3-yl)phenyl)-9H-fluorene-2-amine; HT211), 2-(4-(9,10-di(naphthalene)-2-yl) anthracene-2-yl) phenyl)-1-phenyl-1H-benzo-[D]imidazole (2-(4-(9,10-di(naphthalene-2-yl) anthracene-2-yl)phenyl)-1-phenyl-1H-benzo-[D]imidazole; LG201).

Next, referring to FIG. 19, the opposite electrode 223 is formed in the first display area DA1 and the second display area DA2 entirely on the weak adhesion layer WAL.

Because the deposition material for the opposite electrode 223 has weak adhesive force with the weak adhesion layer WAL, the opposite electrode 223 is not formed in the opening area TAH on the upper surface of the weak adhesion layer WAL as shown in, for example, FIG. 18.

As described above, the display apparatus 1 may be manufactured by sequentially forming the opposite electrode 223 and the encapsulation layer 300.

Embodiments of the present disclosure provide an apparatus for manufacturing a display apparatus and a method of manufacturing the display apparatus having improved deposition quality of the display apparatus and an improved transmittance by using a mask assembly having a more precisely formed opening.

Aspects and features of the present disclosure are not limited to those described above and other aspects and features not mentioned herein may be clearly understood by those of ordinary skill in the art from the following claims.

It should be understood that embodiments described herein should be considered in a descriptive sense and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. An apparatus for manufacturing a display apparatus, the apparatus comprising:
a mask assembly facing a display substrate, the mask assembly comprises:
a mask frame having an opening area;
a first mask on the mask frame and having a first opening; and
a second mask on the first mask and having a plurality of second openings overlapping with the first opening and positioned within a circumference of the first opening in a plan view, a corner curvature radius of each of the second openings being 6 μm or less; and
a deposition source facing the mask assembly on a side opposite the display substrate.

2. The apparatus of claim 1, wherein a shortest distance between two adjacent ones of the second openings is 10 μm or less.

3. The apparatus of claim 2, wherein a minimum width of a rib of the second mask defining the second openings is 10 μm or less.

4. The apparatus of claim 1, wherein a manufacturing tolerance at a point of a circumference of each of the second openings is ±1.5 μm or less.

5. The apparatus of claim 4, wherein an average manufacturing tolerance of each of the second openings is ±1.5 μm or less.

6. The apparatus of claim 1, wherein the second mask comprises a hump protruding from an inner surface of the second openings, and
wherein a height from one surface of the second mask facing the display substrate to the hump is 0.5 μm or less.

7. The apparatus of claim 6, wherein a width of the hump protruding from the inner surface of the second opening in the plan view is 1 μm or less.

8. The apparatus of claim 1, wherein the display substrate has a first display area and a second display area at least partially surrounded by the first display area in the plan view, and
wherein the first opening is at a position corresponding to the second display area in the plan view.

9. The apparatus of claim 8, wherein the second display area has a transmissive area at where a display element is not arranged, and
wherein the second openings are at a position corresponding to the transmissive area in the plan view.

10. A method of manufacturing a display apparatus, the method comprising:
arranging a display substrate inside a chamber;
manufacturing a mask assembly, the mask assembly comprising a first mask having a first opening and a second mask having a second opening, the second mask being manufactured by electro-forming;
arranging the mask assembly to face the display substrate; and
sublimating a deposition material to pass through the mask assembly to be deposited on the display substrate.

11. The method of claim 10, wherein the manufacturing of the second mask using electro-forming comprises:
arranging a photoresist on a mask substrate;
arranging an exposure mask having an exposure opening on the photoresist;
removing the photoresist in a region corresponding to the exposure opening by developing the photoresist;
plating a metal on the region from which the photoresist is removed; and
removing the remaining photoresist and the mask substrate.

12. The method of claim 10, wherein a curvature radius of a corner of the second opening is 6 μm or less.

13. The method of claim 10, wherein the second mask has a plurality of the second openings, and
wherein the second openings overlap with the first opening and are positioned within a circumference of the first opening in a plan view.

14. The method of claim 13, wherein a shortest distance between two adjacent ones of the second openings is 10 μm or less.

15. The method of claim 14, wherein a minimum width of a rib of the second mask defining the second openings is 10 μm or less.

16. The method of claim 10, wherein the second mask comprises a hump protruding from an inner surface of the second opening, and
wherein a height from one surface of the second mask facing the display substrate to the hump is 0.5 μm or less.

17. The method of claim 16, wherein a width of the hump protruding from the inner surface of the second opening in a plan view is 1 μm or less.

18. The method of claim 1, wherein the display substrate has a first display area and a second display area at least partially surrounded by the first display area in a plan view, and
wherein the arranging of the mask assembly comprising aligning the first opening at a position corresponding to the second display area in the plan view.

19. The method of claim 18, wherein the second display area has a transmissive area at where a display element is not arranged, and
wherein the arranging of the mask assembly comprises aligning the second opening at a position corresponding to the transmissive area in the plan view.

20. The method of claim 10, wherein an average manufacturing tolerance of the second opening is ±1.5 μm or less.
